(19) United States
(12) Patent Application Publication
(10) Pub. No.: US 2015/0349108 A1
(43) Pub. Date: Dec. 3, 2015

(54) ELECTRODE STRUCTURE FOR NITRIDE SEMICONDUCTOR DEVICE, AND NITRIDE SEMICONDUCTOR FIELD EFFECT TRANSISTOR

(71) Applicant: SHARP KABUSHIKI KAISHA, Osaka-shi, Osaka (JP)

(72) Inventor: Koichiro FUJITA, Osaka-shi (JP)

(73) Assignee: SHARP KABUSHIKI KAISHA, Osaka-shi, Osaka (JP)

(21) Appl. No.: 14/410,220

(22) PCT Filed: Jun. 26, 2013
(86) PCT No.: PCT/JP2013/067518

§ 371 Date: Dec. 22, 2014

(30) Foreign Application Priority Data
Jun. 29, 2012 (JP) 2012-147135
Jun. 18, 2013 (JP) 2013-127606

(51) Int. Cl. H01L 29/778; H01L 29/417; H01L 29/20

(52) U.S. Cl. CPC H01L 29/7787; H01L 29/2003; H01L 29/41725

(57) ABSTRACT

An electrode structure for nitride semiconductor device according to an embodiment of the invention includes a source electrode and a drain electrode provided from recesses of a nitride semiconductor multilayer structure to a surface of an insulating film so as to be in contact with the surface of the nitride semiconductor multilayer structure between the insulating film and the opening edges of the recesses. According to the structure of the ohmic electrodes, ON-state maximum electric field at ends of the source electrode and the drain electrode adjacent to the nitride semiconductor multilayer structure can be reduced so that the ON-state withstand voltage can be improved, as compared with an electrode structure in which end edge portions of ohmic electrodes are sandwiched between a nitride semiconductor multilayer structure and an insulating film.

### TECHNICAL FIELD

The present invention relates to an electrode structure for nitride semiconductor device, as well as a nitride semiconductor field effect transistor, in which ohmic electrode is provided at a recess formed in a nitride semiconductor multilayer structure having a heterointerface.

### BACKGROUND ART

There is an electrode structure for nitride semiconductor device of PTL1 (JP 4333652 B2), in which a recess is provided in a nitride semiconductor multilayer structure and ohmic electrode is provided at the recess so as to achieve a reduction of the contact resistance.

Also, a nitride semiconductor field effect transistor including such an electrode structure as described above is shown in PTL2 (JP 2011-249439 A). In this nitride semiconductor field effect transistor, as shown in FIG. 21, a nitride semiconductor multilayer structure 1502 is provided on a Si substrate 1501, and a source electrode 1505, a drain electrode 1506 and a gate electrode 1507 are provided on the nitride semiconductor multilayer structure 1502.

The nitride semiconductor multilayer structure 1502 is so constructed that an AlN buffer layer 1521, an undoped GaN layer 1523 and an undoped AlGaN layer 1524 are provided sequentially on the Si substrate 1501. In this nitride semiconductor multilayer structure 1502, recesses are provided so as to extend from the surface through a heterointerface between the undoped GaN layer 1523 and the undoped AlGaN layer 1524, and the source electrode 1505 and the drain electrode 1506 are formed at these recesses. Also, in the undoped AlGaN layer 1524, a recess is provided between the source electrode 1505 and the drain electrode 1506 so as not to reach the heterointerface, and the gate electrode 1507 is provided at this recess.

The source electrode 1505 and the drain electrode 1506 have flanges 1505A, 1506A extending so as to be in contact with an upper surface of the undoped AlGaN layer 1524. On a region ranging from the flange 1505A of the source electrode 1505 to the flange 1506A of the drain electrode 1506, a first insulating film 1511 made from aluminum nitride is formed so as to cover the upper surface of the undoped AlGaN layer 1524 and the gate electrode 1507. Further, a second insulating film 1512 made from silicon nitride is provided on the first insulating film 1511. The second insulating film 1512 has a through hole provided therein so as to allow the first insulating film 1511 to be exposed between the gate electrode 1507 and the drain electrode 1506. A field plate 1515 is provided so as to fill the through hole of the second insulating film 1512 and extend on the second insulating 1512 to reach the source electrode 1505. The field plate 1515 is intended to relax the electric field concentration in vicinity of the gate electrode so that improvement of the gate withstand voltage can be achieved.

### CITATION LIST

### Patent Literature

PTL1: JP 4333652 B2
PTL2: JP 2011-249439 A

### SUMMARY OF INVENTION

### Technical Problem

As for the nitride semiconductor field effect transistor as a switching device, generally, the withstand voltage is expressed by OFF-state withstand voltage (OFF withstand voltage).

FIG. 19 schematically shows a structure around the electrode in a field effect transistor. In the structure around the electrode, end portions of a source electrode 1301 and a drain electrode 1302 are overlaid with an end portion of an insulating film 1307. This field effect transistor is a normally-ON transistor in which a channel (two-dimensional electron gas) 1311 is formed in vicinity of a heterojunction. As a voltage of −10 V is applied to a gate electrode 1303, a region 1305 depicted in broken line in the channel 1311 is depleted so that the transistor is turned off. A voltage of 0 V is applied to the source electrode 1301 while a voltage of e.g. 600 V is applied to the drain electrode 1302.

In the depletion region 1305, positive space charges exist, by which a high electric field region 1306 encircled by one-dot chain line at an end 1303A of the gate electrode 1303 is formed. Therefore, it is known that the OFF withstand voltage can be improved by an increase of a withstand voltage of the gate structure.

However, the present inventors newly found out through various experiments that upon an OFF-to-ON switching of the field effect transistor from the OFF state shown in FIG. 19 to an ON state shown in FIG. 20 with a voltage of 0 V applied to the gate electrode 1303, a high voltage (600 V at maximum) is instantaneously applied to an end 1302A of the drain electrode 1302, by which a high electric field region is formed at a region 1308 encircled by one-dot chain line near the end 1302A of the drain electrode 1302.

From this finding, it has proved that as to the withstand voltage of a field effect transistor as a switching device, it is important to improve not only the OFF-state withstand voltage (OFF withstand voltage) but also the ON-state withstand voltage (ON withstand voltage).

Accordingly, an embodiment of the present invention is directed to provide an electrode structure for nitride semiconductor device, as well as a nitride semiconductor field effect transistor, capable of reducing the electric field at an end portion of an ohmic electrode and moreover improving the ON-state withstand voltage (ON withstand voltage).

### Solution to Problem

An electrode structure for nitride semiconductor device of an embodiment of the present invention comprises: a nitride semiconductor multilayer structure having a heterointerface and further having a recess formed from a surface thereof toward the heterointerface; an insulating film provided on the surface of the nitride semiconductor multilayer structure so as to be separated by a predetermined distance from an opening edge of the recess along the surface of the nitride semiconductor multilayer structure; and an ohmic electrode provided from the recess of the nitride semiconductor multilayer structure to a surface of the insulating film so as to be in contact with the surface of the nitride semiconductor multilayer structure between the insulating film and the opening edge of the recess.

According to the embodiment of this invention, the ohmic electrode is provided from the recess of the nitride semiconductor multilayer structure to the surface of the insulating film so as to be in contact with the surface of the nitride semiconductor multilayer structure between the insulating film and the opening edges of the recess. Therefore, the ON-state maximum electric field at an end of the ohmic electrode adjacent to the nitride semiconductor multilayer structure can be reduced so that the ON withstand voltage can be improved, as compared with prior-art electrode structure in which end edge portions of the ohmic electrodes are sandwiched between the nitride semiconductor multilayer structure and the insulating film.

In an electrode structure for nitride semiconductor device according to an embodiment, a first distance between an imaginary line extended from the opening edge of the recess in a normal direction of the surface of the nitride semiconductor multilayer structure and an outer edge of the ohmic electrode on the surface of the insulating film may be equal to or larger than a double of a second distance by which the insulating film is separated from the opening edge of the recess.

According to this embodiment, the ON-state maximum electric field at the end of the ohmic electrode can be reduces reliably so that the ON withstand voltage can be improved, as compared with a case in which the first distance is smaller than a double of the second distance.

In an electrode structure for nitride semiconductor device according to an embodiment, the insulating film may include a silicon nitride film or compose a silicon nitride film, a silicon oxynitride film, a silicon carbonitride film or an aluminum nitride film.

According to this embodiment, use of the insulating film allows a reduction of the current collapse to be achieved. The term, current collapse, refers to a phenomenon that on-resistance of a transistor in high-voltage operation becomes higher relative to on-resistance of the transistor in low-voltage operation.

In an electrode structure for nitride semiconductor device according to an embodiment, the nitride semiconductor multilayer structure may include: a first GaN-based semiconductor layer; and a second GaN-based semiconductor layer stacked on the first GaN-based semiconductor layer to from a heterointerface with the first GaN-based semiconductor layer.

According to this embodiment, since the nitride semiconductor multilayer structure is composed of a first GaN-based semiconductor layer and a second GaN-based semiconductor layer, there can be provided an electrode structure for nitride semiconductor device suitable for a high-frequency, high-power device.

In a nitride semiconductor field effect transistor according to an embodiment, the nitride semiconductor field effect transistor may comprise: the electrode structure for nitride semiconductor device; a source electrode formed, from the ohmic electrode; a drain electrode formed from the ohmic electrode; and a gate electrode provided on the nitride semiconductor multilayer structure.

According to this embodiment, there can be provided a nitride semiconductor field effect transistor capable of improving the ON-state withstand voltage, i.e., ON withstand voltage.

### Advantageous Effects of Invention

According to this invention, since the ohmic electrode is provided from the recess of the nitride semiconductor multilayer structure to the surface of the insulating film so as to be in contact with the surface of the nitride semiconductor multilayer structure between the insulating film and the opening edge of the recess of the nitride semiconductor multilayer structure, the ON-state maximum electric field at the end of the ohmic electrode on one side closer to the nitride semiconductor multilayer structure can be reduced so that the ON withstand voltage can be improved, as compared with prior-art electrode structure in which the end edge portions of the ohmic electrodes are sandwiched between the nitride semiconductor multilayer structure and the insulating film.

### BRIEF DESCRIPTION OF DRAWINGS

FIG. 1 is a sectional view of a GaN-based field effect transistor having an embodiment of the electrode structure for nitride semiconductor device according to a first embodiment of the present invention;

FIG. 2 is a process sectional view for explaining a production process of the GaN-based field effect transistor;

FIG. 3 is a process sectional view subsequent to FIG. 2;

FIG. 4 is a process sectional view subsequent to FIG. 3;

FIG. 5 is a process sectional view subsequent to FIG. 4;

FIG. 6 is a process sectional view subsequent to FIG. 5;

FIG. 7 is a process sectional view subsequent to FIG. 6;

FIG. 8 is a process sectional view subsequent to FIG. 7;

FIG. 9 is a sectional view showing main part of the electrode structure of the embodiment;

FIG. 10 is a sectional view showing main part of an electrode structure which is a comparative example;

FIG. 11 is a sectional view showing main part of an electrode structure according to a related art;

FIG. 12 is a chart prepared from simulation results of maximum electric field in the electrode structures of a working example of the embodiment, the comparative example, and the related art example;

FIG. 13 is a chart of maximum electric field in a nitride semiconductor multilayer structure prepared from the simulation results;

FIG. 14 is a chart of maximum electric field in an insulating film prepared from the simulation results;

FIG. 15 is an equipotential line view representing an electric potential distribution of the comparative example according to the simulations;

FIG. 16 is an equipotential line view representing an electric potential distribution of the working example according to the simulations;

FIG. 17 is an equipotential line view representing an electric potential distribution of another working example according to the simulations;

FIG. 18 is an equipotential line view representing an electric potential distribution of the related art example according to the simulations;

FIG. 19 is a view schematically showing a cross section of the field effect transistor in the OFF state;

FIG. 20 is a view schematically showing a cross section of the field effect transistor upon a switching from OFF to ON state; and

FIG. 21 is a sectional view of a field effect transistor having an electrode structure for nitride semiconductor device according to PTL2.

### DESCRIPTION OF EMBODIMENTS

Hereinbelow, the present invention will be described in detail by way of embodiments thereof illustrated in the accompanying drawings.

### First Embodiment

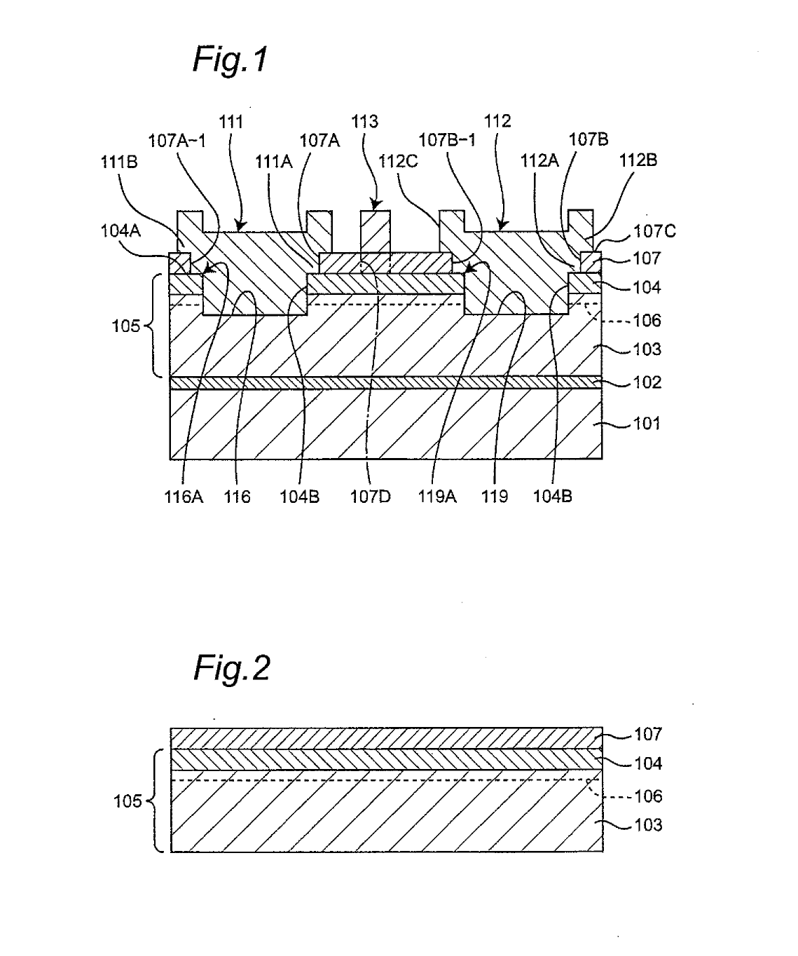

FIG. 1 is a sectional view of a nitride semiconductor device having an embodiment of the electrode structure according to a first embodiment of the invention. This nitride semiconductor device is a GaN-based HFET (Hetero-junction Field Effect Transistor).

As shown in FIG. 1, the nitride semiconductor device has a Si substrate 101, an undoped AlGaN buffer layer 102, an undoped GaN channel layer 103 as an example of a first GaN-based semiconductor layer and an undoped AlGaN barrier layer 104 as an example of a second GaN-based semiconductor layer. The undoped AlGaN buffer layer 102, the undoped GaN channel layer 103 and the undoped AlGaN barrier layer 104 are provided on the Si substrate 101 in this order. A 2DEG (two-dimensional electron gas) layer 106 is generated in vicinity of a heterointerface between the undoped GaN channel layer 103 and the undoped AlGaN barrier layer 104. The undoped GaN channel layer 103 and the undoped AlGaN barrier layer 104 constitute a nitride semiconductor multilayer structure 105.

In addition, the GaN channel layer 103 may be replaced with an AlGaN layer having such a composition that its band gap is smaller than that of the AlGaN barrier layer 104. Also, for example, a GaN layer having a thickness of about 1 nm may be provided as a cap layer on the AlGaN barrier layer 104.

In the nitride semiconductor multilayer structure 105, a recess 116 and a recess 119 are provided at intervals from each other. The recesses 116 and 119 extend from a surface 104A of the AlGaN barrier layer 104 so as to reach the GaN channel layer 103 through the AlGaN barrier layer 104 and the 2DEG layer 106. Also, an insulating film 107 is formed on the surface 104A of the AlGaN barrier layer 104. This insulating film 107 is provided outside the recesses 116 and 119. The insulating film 107 is separated by a predetermined distance from opening edges 116A and 119A of the recesses 116 and 119 along the surface 104A of the AlGaN barrier layer 104. That is, side walls 107A-1 and 107B-1 of the openings 107A and 107B provided in the insulating film 107 are separated by a predetermined distance from the opening edges 116A and 119A along the surface 104A of the AlGaN barrier layer 104.

A source electrode 111, which is an ohmic electrode, is provided at the recess 116, while a drain electrode 112 is provided at the recess 119. The source electrode 111 extends through the opening 107A of the insulating film 107 and fills the recess 116. This source electrode 111 has a first flange 111A extending from the opening edge 116A of the recess 116 along the surface 104A of the AlGaN barrier layer 104 to the side wall 107A-1 of the opening 107A of the insulating film 107, and has a second flange 111B provided on a surface 107C of the insulating film 107.

Also, the drain electrode 112 extends through the opening 107B of the insulating film 107 and fills the recess 119. This drain electrode 112 has a first flange 112A extending from the opening edge 119A of the recess 119 along the surface 104A of the AlGaN barrier layer 104 so as to reach the side wall 107B-1 of the opening 107B of the insulating film 107, and has a second flange 112B provided on the surface 107C of the insulating film 107.

As described above, the source electrode 111 and the drain electrode 112 are provided from the recesses 116 and 119 of the nitride semiconductor multilayer structure 105 to the surface 107C of the insulating film 107 so as to be in contact with the surface 104A of the AlGaN barrier layer 104 in the nitride semiconductor multilayer structure 105 between the insulating film 107 and the opening edges 116A and 119A of the recesses 116 and 119.

The source electrode 111 and the drain electrode 112 are formed from a multilayer of Ti/Al/TiN in which Ti, Al, TiN are layered in order, as an example.

Further, a gate electrode 113 is formed between the source electrode 111 and the drain electrode 112 on the insulating film 107. This gate electrode 113 is made from TiN or WN as an example.

In addition, under the condition that an opening 107D is provided in the insulating film 107 so as to make the surface of the AlGaN barrier layer 104 exposed as shown by one-dot chain line in FIG. 1, the gate electrode 113 may be provided at the opening 107D as a Schottky electrode that extends through the insulating film 107 so as to reach the AlGaN barrier layer 104.

In the nitride semiconductor device constituted as described above, a channel is formed by the two-dimensional electron gas (2DEG) layer 106 generated in vicinity of the interface between the GaN channel layer 103 and the AlGaN barrier layer 104, and this channel is controlled by applying a voltage to the gate electrode 113 so that the HFET having the source electrode 111, the drain electrode 112 and the gate electrode 113 is turned on and off. The HFET is a normally-ON type transistor that when a negative voltage is applied to the gate electrode 113, a depletion layer is formed in the GaN layer 103 under the gate electrode 113 to turn off the HFET and when zero volt is applied to the gate electrode 113, no depletion layer is formed in the GaN layer 103 under the gate electrode 113 to turn on the HFET.

Next, a production method for the nitride semiconductor device will be described with reference to FIGS. 2 to 8. In FIGS. 2 to 8, for an easier seeing of the drawings, neither the Si substrate nor the undoped AlGaN buffer layer is shown.

First, as shown in FIG. 2, an undoped AlGaN buffer layer (not shown), an undoped GaN channel layer 103 and an undoped AlGaN barrier layer 104 are formed sequentially on a Si substrate (not shown) by using MOCVD (Metal Organic Chemical Vapor Deposition) process. The undoped GaN channel layer 103 has a thickness of 1 μm as an example, and the undoped AlGaN barrier layer 104 has a thickness of 30 nm as an example. These GaN channel layer 103 and AlGaN barrier layer 104 constitute a nitride semiconductor multilayer structure 105. In FIG. 2, reference sign 106 denotes a two-dimensional electron gas (2DEG) layer 106 formed in vicinity of the heterointerface between the GaN channel layer 103 and the AlGaN barrier layer 104.

Next, for example, a silicon nitride film 107 having a thickness of 200 nm is deposited on the AlGaN barrier layer 104 by plasma CVD (Chemical Vapor Deposition) process to form an insulating film 107. The growth temperature for this insulating film 107 is set to 225° C. as an example in this case, but may be set within a range of 200° C. to 400° C. Also, the film thickness of the insulating film 107 is set to 200 nm as an example in this case, but may be set within a range of 20 nm to 400 nm.

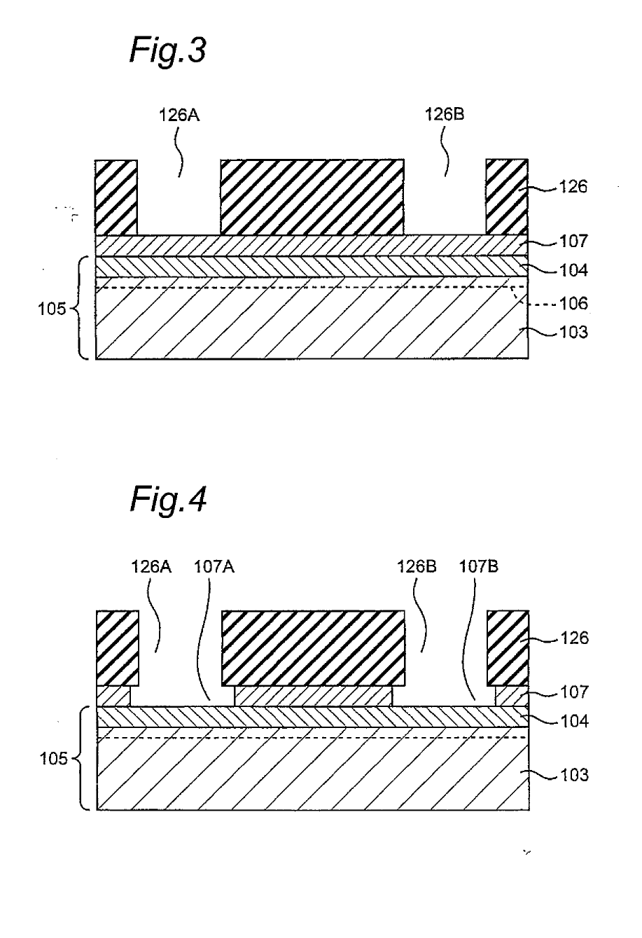

Next, as shown in FIG. 3, a photoresist layer 126 is formed on the insulating film 107 and then openings 126A and 126B are formed in the photoresist layer 126 by exposure to light and development processes. Then, wet etching is performed under the condition that the photoresist layer 126 having the openings 126A and 126B formed therein is used as a mask. As a result, as shown in FIG. 4, openings 107A and 107B are formed in the insulating film 107. In addition, the formation of the openings 107A and 107B in the insulating film 107 may be done by dry etching instead of the wet etching.

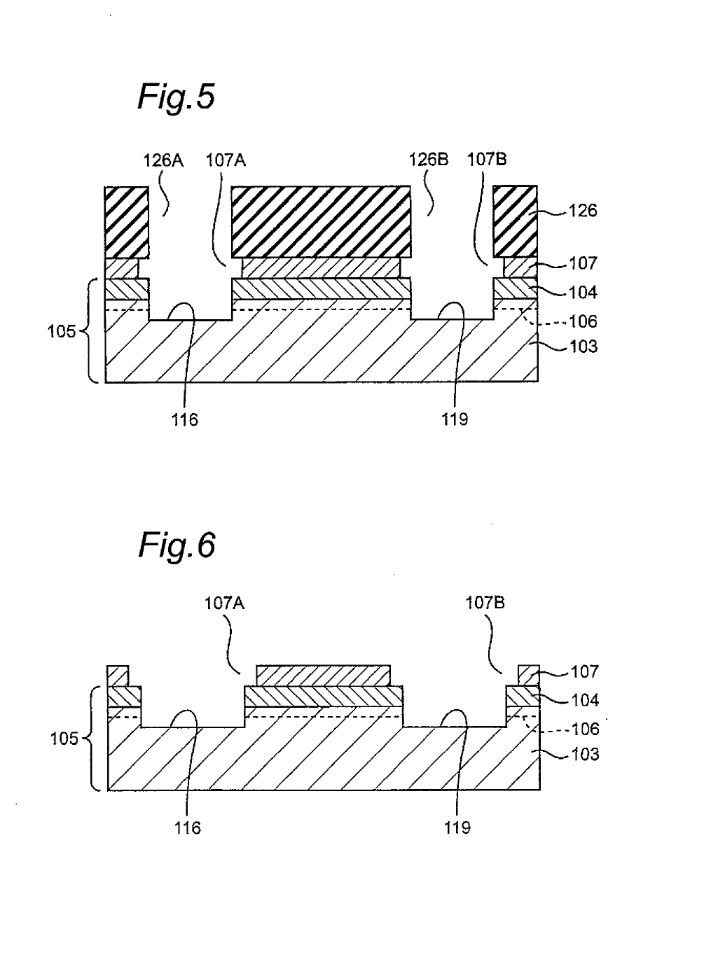

Subsequently, as shown in FIG. 5, dry etching is performed by using the photoresist layer 126 having the openings 126A and 126B formed therein as a mask, by which recesses 116 and 119 are formed from the AlGaN barrier layer 104 to the GaN channel layer 103.

Next, as shown in FIG. 6, the photoresist layer 126 is removed. Subsequently, oxygen plasma processing and acid cleaning are performed. These oxygen plasma processing and acid cleaning may not be performed.

Next, the insulating film 107 is subjected to anneal. This anneal is executed, in this case, in a nitrogen atmosphere at 500° C. for 5 minutes, as an example. The temperature for the anneal may be set within a range of 500° C. to 850° C. as an example.

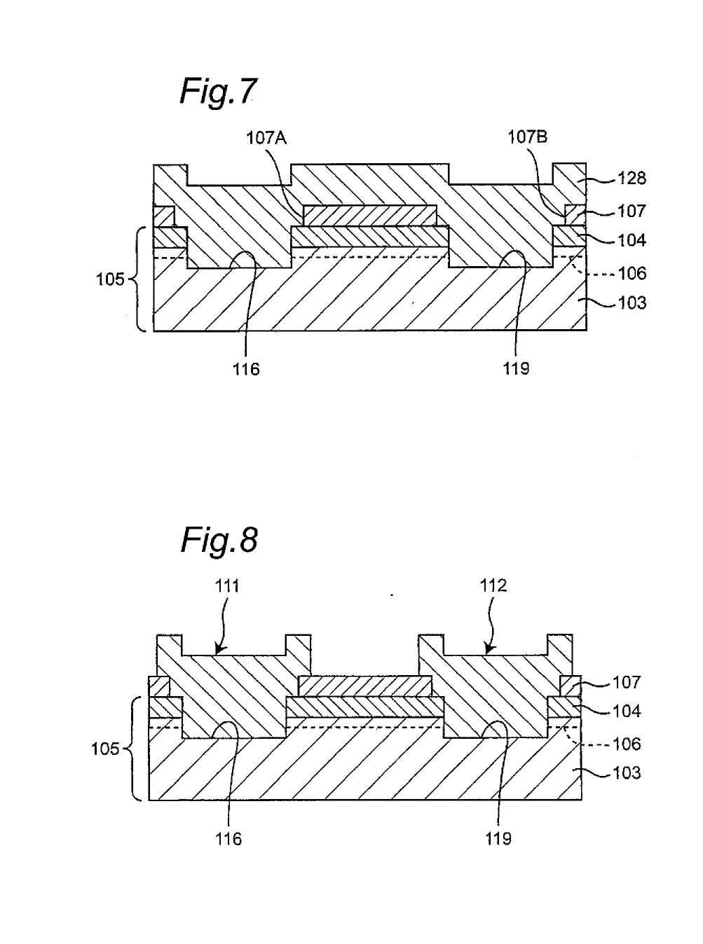

Next, as shown in FIG. 7, Ti, Al and TIN layers are sequentially stacked on the insulating film 107 and in the recesses 106 and 109 by sputtering to make up a multilayer of Ti/Al/TiN, so that a multilayer metal film 128 to serve as the ohmic electrode is formed. In this case, the TiN layer is a cap layer for protecting the a multilayer of Ti/Al from subsequent steps.

In this embodiment, for the sputtering, a ratio α/β of a layer thickness α (nm) of the Ti layer to a layer thickness β (nm) of the Al layer is set, for example, to within a range of 2/100 to 40/100 so that an atomic ratio of Ti to Al in the TiAl alloy of the ohmic electrodes formed subsequent to a later-described ohmic annealing process falls within a range of 2.0 to 40 atom % (e.g., 8 atom %).

In addition, instead of the above sputtering, the Ti and Al layers may be vapor deposited.

Next, as shown in FIG. 8, patterns of ohmic electrodes 111 and 112 are formed by using normal photolithography and dry etching.

Then, the substrate with the ohmic electrodes 111 and 112 formed thereon is annealed at temperatures of e.g. 400° C. to 500° C. for 10 minutes or more, by which ohmic contacts can be obtained between the two-dimensional electron gas (2DEG) layer 106 and the ohmic electrodes 111 and 112. In this case, the contact resistance can be reduced to a large extent, as compared with cases where the substrate is annealed at high temperatures over 500° C. (e.g., 600° C. or higher). Performing the annealing of the substrate at lower temperatures within the range of 400° C. to 500° C. makes it possible to suppress diffusion of the electrode metal into the insulating film 107, so that characteristics of the insulating film 107 are never adversely affected. The annealing of substrate at lower temperatures makes it possible to prevent deterioration of current collapse and electric characteristic degradations due to denitrification from the GaN channel layer 103. The annealing time, although set to 10 minutes or more in this case, may appropriately be set to a time duration that allows Ti to be sufficiently diffused into Al. The term ‘current collapse’ refers to a phenomenon that on-resistance of a transistor in high-voltage operation becomes higher relative to on-resistance of the transistor in low-voltage operation.

The ohmic electrodes 111, 112 become the source electrode 111 and the drain electrode 112, and a gate electrode 113 made from TiN or WN or the like is formed between the source electrode 111 and the drain electrode 112 in subsequent process.

According to this embodiment, the source electrode 111 and the drain electrode 112 as the ohmic electrode are provided from the recesses 116 and 119 of the nitride semiconductor multilayer structure 105 to the surface 107C of the insulating film 107 so as to be in contact with the surface of the nitride semiconductor multilayer structure 105 between the insulating film 107 and the opening edges 116A and 119A of the recesses 116 and 119.

According to the structure of the source electrode 111 and the drain electrode 112, which are ohmic electrodes as described above, it has proved that the ON-state maximum electric field at ends of the ohmic electrodes, i.e., the source electrode 111 and the drain electrode 112 adjacent to the nitride semiconductor multilayer structure 105 can be reduced so that the ON withstand voltage can be improved, as compared with an electrode structure in which end edge portions of the ohmic electrodes are sandwiched between the nitride semiconductor multilayer structure and the insulating film, as will be described below.

(Description of Simulation Results)

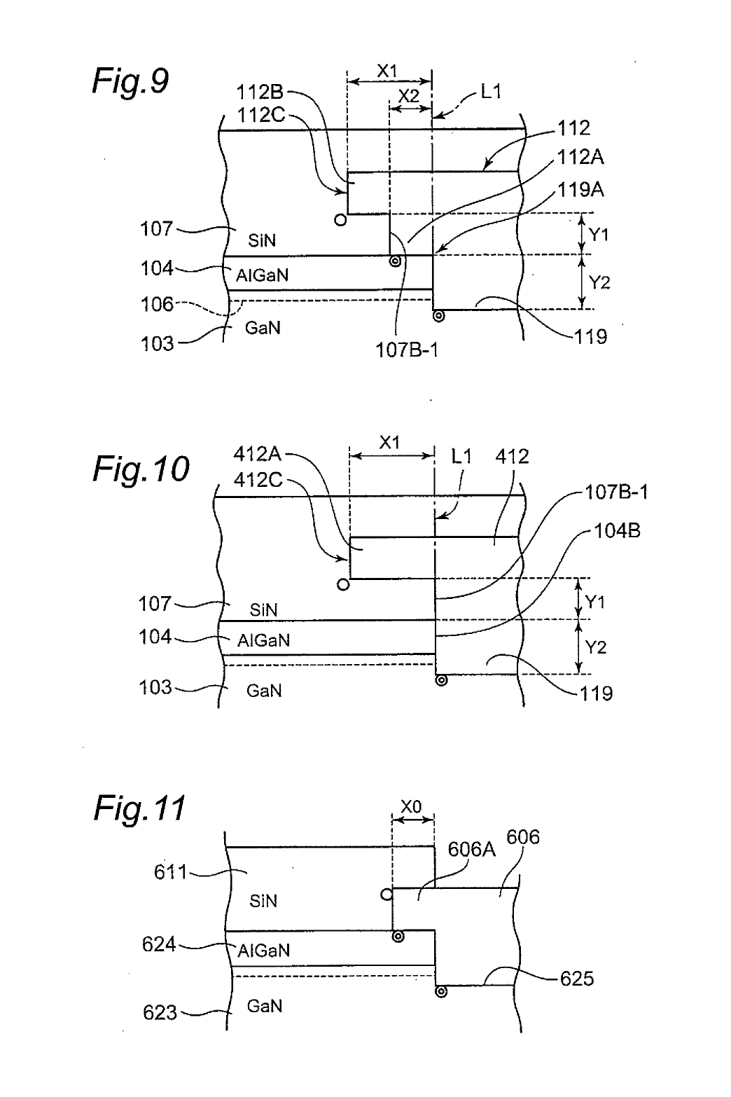

Referring to FIGS. 9 to 13, simulation results of the maximum electric field at the end of the drain electrode 112 in the electrode structure of the above embodiment will be described.

In this simulation, as shown in FIG. 9, a film thickness Y1 of the insulating film 107 made from SiN under the second flange 112B of the drain electrode 112 was set to 275 nm. A depth Y2 of the recess 119 in the nitride semiconductor multilayer structure 105 was set to 75 nm. A second distance X2 between the side wall 107B-1 of the opening 107B of the insulating film 107 and the opening edge 119A of the recess 119 was set to 0.3 μm or 0.5 μm. A first distance X1 between an imaginary line L1 extended from the opening edge 119A of the recess 119 in a normal direction of the surface 104A of the AlGaN barrier layer 104 and an outer edge 112C of the drain electrode 112 on the surface 107C of the insulating film 107 was set to 0.8 μm. In the electrode structure shown in FIG. 9, the insulating film 107 is laid over the drain electrode 112. Also in the electrode structure shown in FIG. 9, the film thickness of the insulating film 107 was set to 1175 nm.

A relative dielectric constant of the insulating film 107 was set to 7.0, and a relative dielectric constant of the AlGaN barrier layer 104 and the GaN channel layer 103 was set to 9.5.

FIG. 10 shows a structure of a comparative example which is so constituted that the second distance X2 is set to 0.0 μm in the electrode structure shown in FIG. 9. In this comparative example, the film thickness Y1 of the insulating film 107, the first distance X1, and the depth Y2 of the recess 119 were set to 275 nm, 0.8 μm, and 75 nm, respectively, likewise as in the structure of FIG. 9. That is, in this comparative example, the side wall 107B-1 of the opening of the insulating film 107 and the side wall 104B of the AlGaN barrier layer 104 in the recess 119 are formed generally flush with each other.

FIG. 11 shows an electrode structure which is a conventional example. In this electrode structure, a flange 606A of a drain electrode 606 is overlaid with an insulating film 611. In the conventional example, the thickness of the insulating film 611 was set to 1175 nm, and the depth of a recess 625 provided in a GaN channel layer 623 and an AlGaN barrier layer 624 was set to 75 nm. A length X0 of the flange 606A extending along the surface of the AlGaN barrier layer 624 outside the recess 625 was set to 0.8 μm. A relative dielectric constant of the insulating film 611 was set to 7.0, and a relative dielectric constant of the AlGaN barrier layer 624 and the GaN channel layer 623 was set to 9.5.

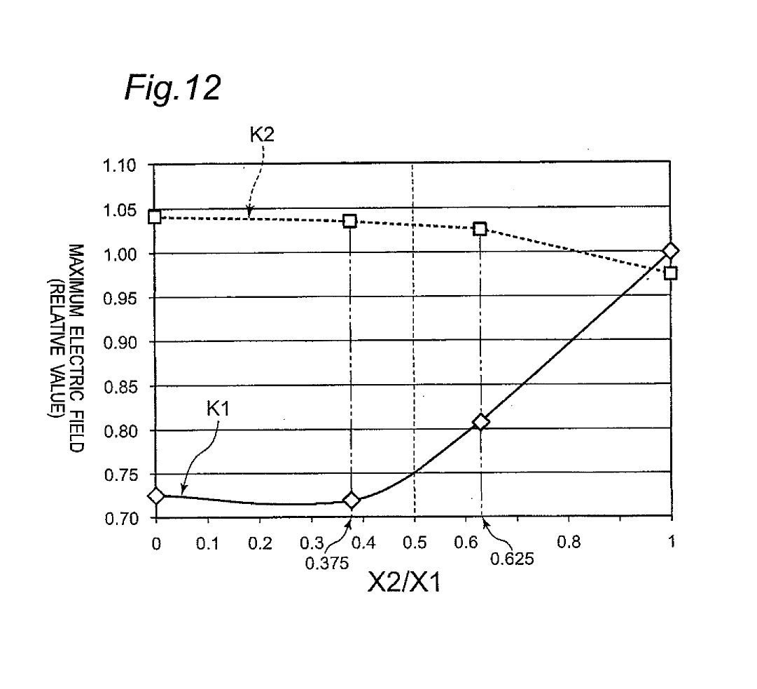

The chart of FIG. 12 was obtained by simulating an electric potential distribution generated at an end of the drain electrode upon applying zero volt to the gate electrode to switch from an OFF state, in which zero volt is applied to the source electrode, 600 volts is applied to the drain electrode and −10 volts is applied to the gate electrode to an On state.

In FIG. 12, open diamonds ⋄ on a solid curve K1 represent maximum electric fields in the nitride semiconductor multilayer structure. On the other hand, open squares □ on a broken curve K2 represent maximum electric fields in the insulating film.

In FIG. 12, the vertical axis represents relative values under the condition that a simulation result of a maximum electric field (the largest value of electric field out of places indicated by double circles) within the nitride semiconductor multilayer structure in the electrode structure of the conventional example of FIG. 11 is assumed as 1.00. Also, the horizontal axis in FIG. 12 represents the value X2/X1 resulting from dividing the second distance X2 by the first distance X1.

In FIG. 12, the value of X2/X1=0 corresponds to the comparative example, while the value of X2/X1=1 corresponds to the conventional example.

That is, open diamonds ⋄ on the solid curve K1 and the open squares □ on the broken curve K2 in FIG. 12 are results of plotting relative values under the condition that the largest value out of an electric field in the AlGaN layer 624 near beneath an outer edge (marked by ⊚ in FIG. 11) of the flange 606A of the drain electrode 606 and an electric field in the GaN layer 623 near beneath an outer edge (marked by ⊚ in FIG. 11) of the bottom of the recess 625 in the electrode structure of the conventional example of FIG. 11 is assumed as 1.00.

In FIG. 12, an open square □ corresponding to (X2/X1)−(0.3/0.8)=0.375 in the horizontal axis represents a relative value of 1.036 of the maximum electric field in the insulating film 107 beneath the outer edge 112C (marked by ∘ in FIG. 9) of the drain electrode 112 under the condition that the second distance X2 in the working example of FIG. 9 is set to 0.3 μm. And, an open diamond ⋄ corresponding to (X2/X1)=0.375 in the horizontal axis represents a relative value of 0.719 of the maximum electric field in the nitride semiconductor multilayer structure 105 under the condition that the second distance X2 in the working example of FIG. 9 is set to 0.3 μm. In other words, the open diamond ⋄ represents the relative value that is the larger one of an electric field in the AlGaN layer 104 near beneath the outer edge (marked by ⊚ in FIG. 9) of the first flange 112A of the drain electrode 112 and an electric field in the GaN layer 103 near beneath the outer edge (marked by ⊚ in FIG. 9) of the bottom of the recess 119.

In FIG. 12, an open square □ corresponding to (X2/X1)=(0.5/0.8)=0.625 in the horizontal axis represents a relative value of 1.026 of electric field in the insulating film 107 near beneath the outer edge 112C (marked by ∘ in FIG. 9) of the drain electrode 112 under the condition that the second distance X2 in the working example of FIG. 9 is set to 0.5 μm. And, an open diamond ⋄ corresponding to (X2/X1)=0.625 in the horizontal axis represents a relative value of 0.807 of the maximum electric field in the nitride semiconductor multilayer structure 105 under the condition that the second distance X2 in the working example of FIG. 9 is set to 0.5 μm. In other words, the open diamond ⋄ corresponding to (X2/X1)=0.625 in the horizontal axis represents the larger one of a relative value of electric field in the AlGaN layer 104 near beneath the outer edge (marked by ⊚ in FIG. 9) of the first flange 112A of the drain electrode 112 and a relative value of electric field in the GaN layer 103 near beneath the outer edge (marked by @ in FIG. 9) of the bottom of the recess 119 under the condition that the second distance X2 in FIG. 9 is set to 0.5 μm.

In FIG. 12, an open square □ corresponding to (X2/X1)=0.0 in the horizontal axis represents a relative value of 1.042 of electric field in the insulating film 107 near beneath an outer edge 412C (marked by ∘ in FIG. 10) of a flange 412A of a drain electrode 412 in the comparative example (the second distance X2 is zero) of FIG. 10. And, an open diamond ⋄ corresponding to (X2/X1)=0.0 in the horizontal axis represents a relative value of 0.729 of electric field in the GaN layer 103 near beneath the outer edge (marked by ⊚ mark in FIG. 10) of the bottom of the recess 119 in the comparative example.

In FIG. 12, an open square □ corresponding to (X2/X1)=1.0 in the horizontal axis represents a relative value of 0.979 of electric field in the insulating film 611 near the outer edge (marked by ∘ in FIG. 11) of the flange 606A of the drain electrode 606 in the conventional example of FIG. 11.

A simulation results of FIG. 12 shows that setting the second distance X2 smaller than the first distance X1 makes it possible to reduce the maximum electric field in the nitride semiconductor multilayer structure 105, in comparison to the conventional example.

The simulation results of FIG. 12 shows that setting the second distance X2 equal to or smaller than one half of the first distance X1, i.e., setting the value of (X2/X1) in the horizontal axis equal to or smaller than 0.5 makes it possible to reduce the maximum electric field in the AlGaN layer or the GaN layer to a large extent (25% or more) in comparison to the conventional example. Furthermore, it can be seen that with the second distance X2 set equal to or smaller than one half of the first distance X1, the maximum electric field in the insulating film is suppressed to an increase of 5% or less relative to the conventional example. That is, according to the embodiment of this invention, although the maximum electric field in the insulating film increases by about 5% in comparison to the conventional example, yet the maximum electric field in the nitride semiconductor multilayer structure 105 can be reduced to a large extent, so that the ON-state withstand voltage, i.e., ON withstand voltage can be improved. For improvement of the ON withstand voltage, it is more important to reduce the maximum electric field in the nitride semiconductor multilayer structure than to reduce the maximum electric field in the insulating film.

According to the simulation results of FIG. 12, setting the value of (X2/X1) to within a range of 0.1 to 0.5, more preferably, within a range of 0.3 to 0.4 makes it possible to reduce the maximum electric field in the nitride semiconductor multilayer structure 105.

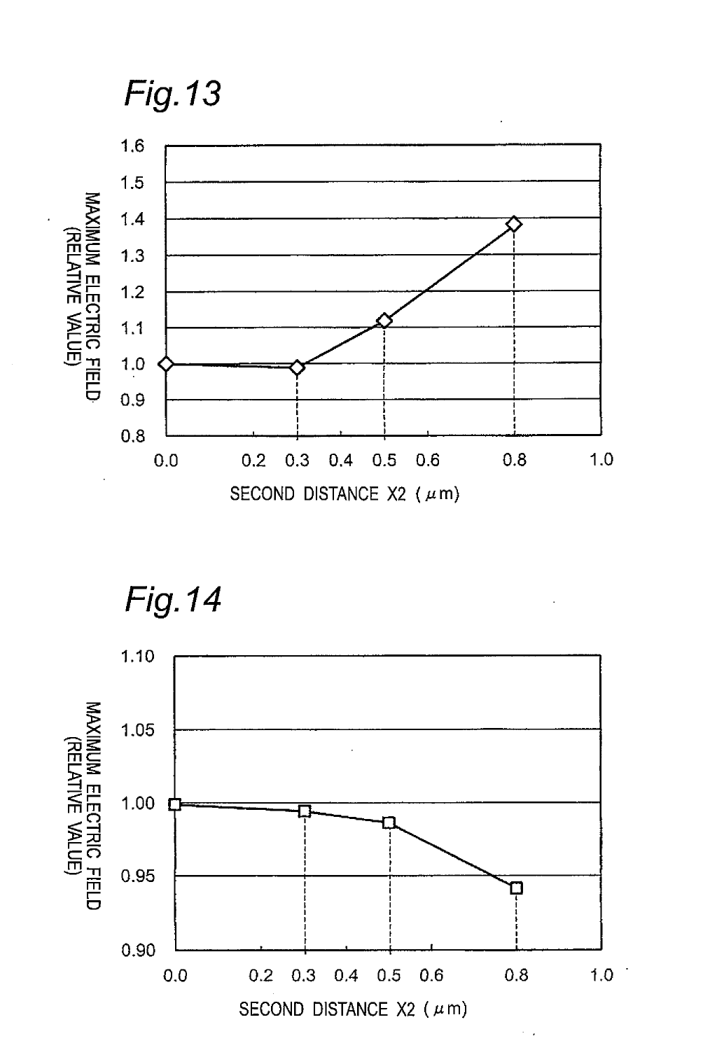

FIG. 13 is a chart in which the horizontal axis represents the second distance X2 (μm) and the vertical axis represents the relative value of maximum electric field in the nitride semiconductor multilayer structure 105. That is, the maximum electric field in the nitride semiconductor multilayer structure 105 with the electrode structure (X2=0.0 μm) of the comparative example shown in FIG. 10 was set to a relative value of 1.00. The first distance X1 (μm) was fixed at 0.8 (μm).

As shown in FIG. 13, when the second distance X2 is 0.3 μm, i.e. (X2/X1)=0.375, the relative value of maximum electric field is 0.986, which is the lowest. As the second distance X2 goes beyond the 0.3 μm, the relative value of maximum electric field increases, so that when the second distance X2 reaches 0.8 μm, i.e. (X2/X1)=1.000, the relative value of maximum electric field reaches 1.371. This structure, in which (X2/X1)=1.000, corresponds to the electrode structure of the conventional example shown in FIG. 11. Therefore, in this working example, in which (X2/X1)=0.375, the maximum electric field in the nitride semiconductor multilayer structure 105 could be reduced by about 30% in comparison to the conventional example.

On the other hand, in FIG. 14, the horizontal axis represents the second distance X2 (μm) and the vertical axis represents the relative value of maximum electric field in the insulating film. That is, the maximum electric field in the insulating film with the electrode structure (X2=0.0 μm) of the comparative example shown in FIG. 10 was set to a relative value of 1.00. The first distance X1 (μm) was fixed at 0.8 (μm).

As shown in FIG. 14, when the second distance X2 is 0.3 μm, i.e. (X2/X1)=0.375, the relative value of maximum electric field is 0.995, showing that the maximum electric field in the insulating film reduced in comparison to the comparative example. In the electrode structure of the conventional example, in which the second distance X2 was 0.8 (μm), the relative value of maximum electric field in the insulating film was the lowest, being 0.940. With (X2/X1)=0.375, the relative value of maximum electric field is 0.995, showing an increase of about 5% in comparison to the conventional example.

According to this working example, although the maximum electric field in the insulating film increases by about 5% in comparison to the conventional example, yet the maximum electric field in the nitride semiconductor multilayer structure 105 can be reduced to a large extent (a decrease of about 30%), so that the ON-state withstand voltage (ON withstand voltage) can be improved. For improvement of the ON withstand voltage, it is more important to reduce the maximum electric field in the nitride semiconductor multilayer structure than to reduce the maximum electric field in the insulating film.

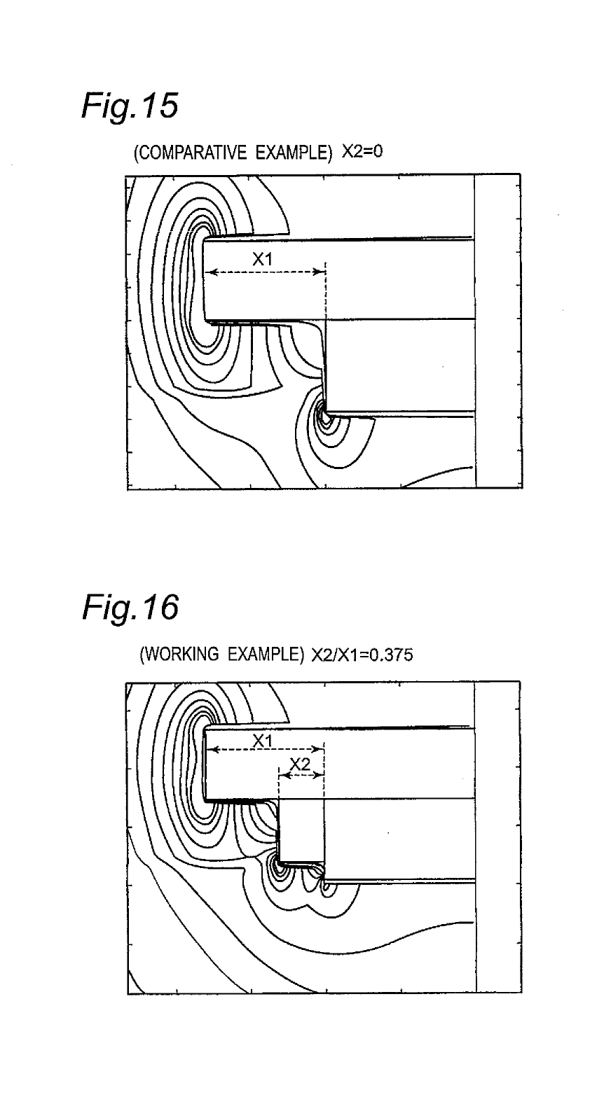

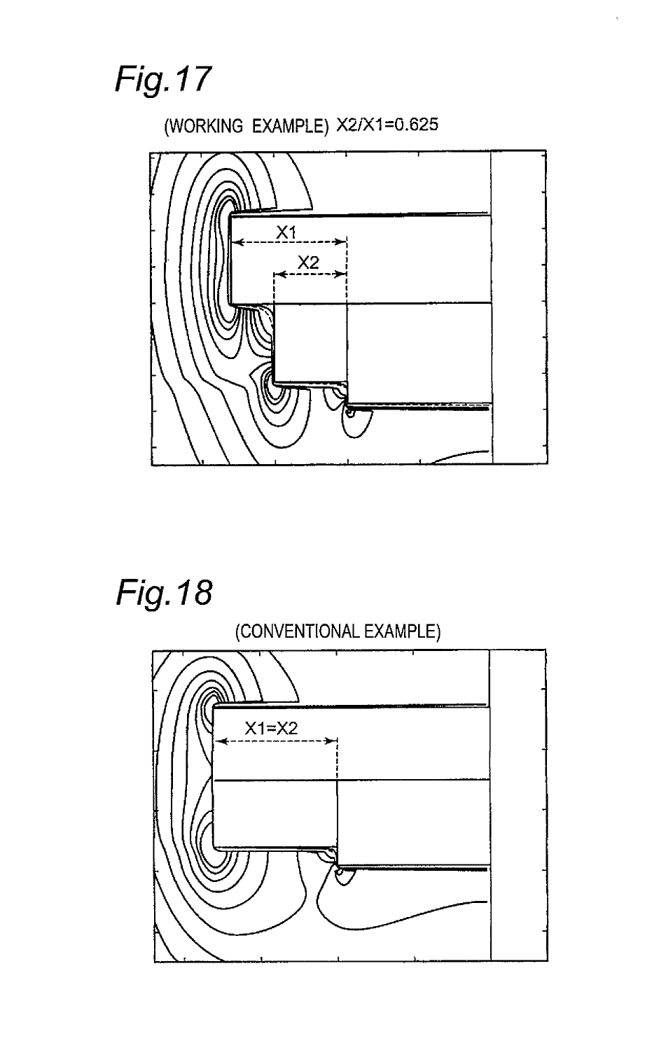

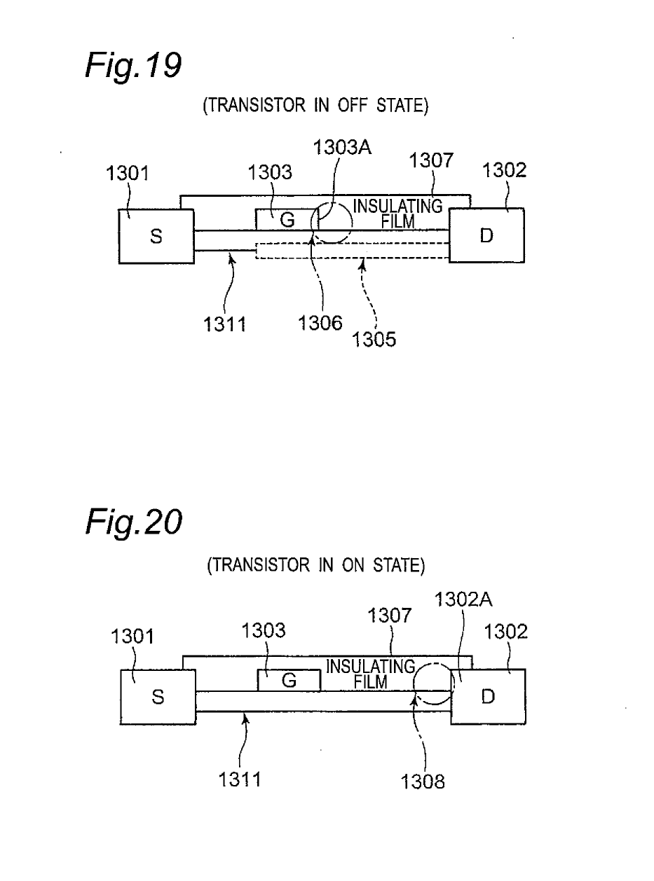

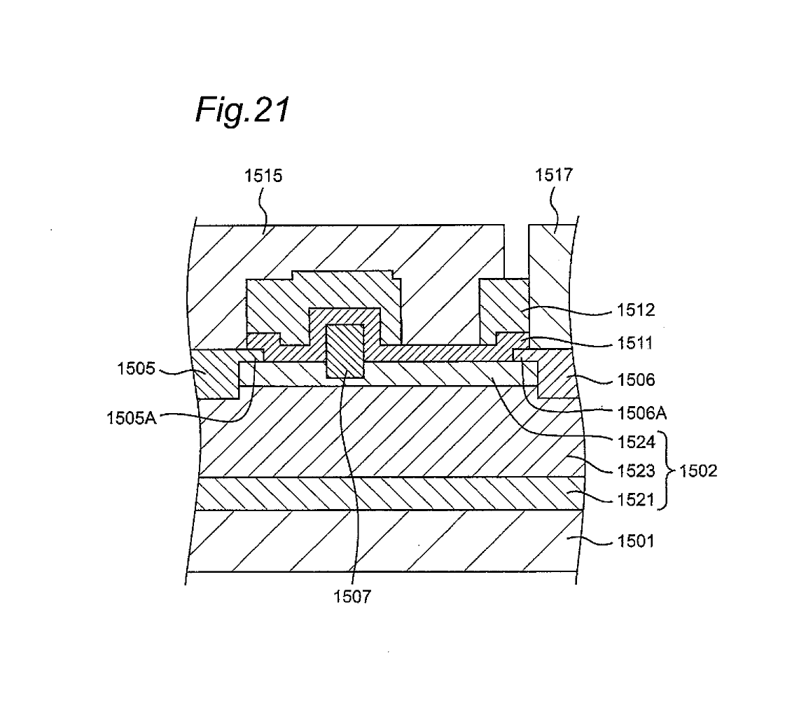

FIG. 15 is an equipotential line view in the comparative example in which (X2/X1) equals 0.0. FIG. 16 is an equipotential line view in this working example (X2/X1=0.375). FIG. 17 is an equipotential line view in this working example (X2/X1=0.625). FIG. 18 is an equipotential line view in the conventional example (X2/X1=1.000). The curved lines of FIGS. 15 to 18 are equipotential lines obtained from the simulations.

In the nitride semiconductor device, the recesses 116 and 119 are provided in the nitride semiconductor multilayer structure 105 so as to extend through the AlGaN barrier layer 104 and the 2DEG layer 106. However, the recesses 116 and 119 may be provided to extend through the AlGaN barrier layer 104 but not to extend through the 2DEG layer 106. Furthermore, the recesses 116 and 119 may be provided not to extend through the AlGaN barrier layer 104.

In the nitride semiconductor device, the gate electrode 113 is provided on the insulating film 107 to constitute a MOS structure. Alternatively, a gate electrode 113 as a Schottky electrode may be provided in the AlGaN barrier layer 104 exposed at an opening provided in the insulating film 107.

In the above embodiment, the multilayer of Ti/Al/TiN is formed to make up the ohmic electrodes. However, TiN layer may not be stacked to form a multilayer of Ti/Al. And Au, Ag, Pt or the like may be stacked on the multilayer of Ti/Al.

In the above embodiment, the nitride semiconductor device has the Si substrate. However, the Si substrate device may have not only the Si substrate, but a sapphire substrate or SiC substrate. A nitride semiconductor layer may be grown on a substrate composed of a nitride semiconductor such as growing an AlGaN layer on a GaN substrate. A buffer layer may be provided between a substrate and a nitride semiconductor layer. An AlN hetero-characteristic improving layer having a layer thickness of about 1 nm may be provided between the AlGaN barrier layer 104 and the GaN channel layer 103 of the nitride semiconductor multilayer structure 105.

As materials of the insulating film 107 in the above nitride semiconductor device, for example, SiNx, SiO₂, AlN, Al₂O₃ and the like are used. In particular, the insulating film 107 is preferably provided in a multilayer film structure composed of a SiN film of decayed stoichiometry formed on the surface of the AlGaN barrier layer 104 for current collapse suppression and a protective film formed from SiO₂ or SiN for surface protection on the SiN film. Further, SiON or SiCN may be used as the material of the insulating film 107. The insulating film 107 may be provided by forming an AlN film on a SiN film and by forming a SiON film on the AlN film.

### Second Embodiment

An electrode structure for nitride semiconductor device according to a second embodiment is so constituted that the insulating film 107 of the first embodiment is replaced with an insulating film including a silicon oxynitride (SiON) film or, an insulating film including a silicon carbonitride (SiCN) film. Use of the insulating film including a SiON film or a SiCN film makes it possible to reduce the current collapse.

Instead of the insulating film including a SiON film, an insulating film composed of a SiON film may be used.

Instead of the insulating film including a SiCN film, an insulating film composed of a SiCN film may be used.

### Third Embodiment

An electrode structure for nitride semiconductor device according to a third embodiment is so constituted that the insulating film 107 of the first embodiment is replaced with an insulating film including an aluminum oxide (Al₂O₃) film or an insulating film including a silicon oxide (SiO₂) film. Use of the insulating film including an Al₂O₃ film or a SiO₂ film makes it possible to reduce the current collapse.

Instead of the insulating film including an Al₂O₃ film, an insulating film composed of an Al₂O₃ film may be used.

Instead of the insulating film including a SiO₂ film, an insulating film composed of a SiO₂ film may be used.

### Fourth Embodiment

An electrode structure for nitride semiconductor device according to a fourth embodiment is so constituted that the insulating film 107 of the first embodiment is replaced with an insulating film including an AlN film. Use of the insulating film including an AlN film makes it possible to reduce the current collapse.

Instead of the insulating film including an AlN film, an insulating film composed of an AlN film may be used.

The invention may be applied not only to the above nitride semiconductor of an HFET of the normally-ON type, but to nitride semiconductor device of the normally-OFF type. Further, the gate electrode may be provided as a Schottky electrode without being limited to those of the insulated-gate structure.

The nitride semiconductor for the nitride semiconductor device of this invention may be a nitride semiconductor expressed by AlₓIn_{y}Ga_{1-x-y}N (x≧0, y≧0, 0≦x+y≦1).

Although specific embodiments of the present invention have been described hereinabove, yet the invention is not limited to the above embodiments and may be carried out as they are changed and modified in various ways within the scope of the invention.

### REFERENCE SIGNS LIST

101 Si substrate
102 undoped AlGaN buffer layer
103 undoped GaN channel layer
104 undoped AlGaN barrier layer
104A surface
104B side wall
105 nitride semiconductor multilayer structure
106 two-dimensional electron gas (2DEG) layer
107 insulating film
107A, 107B opening
107A-1, 107B-1 side wall
111 source electrode
111A first flange
111B second flange
112 drain electrode
112A first flange
112B second flange
112C outer edge
113 gate electrode
116, 119 recess
116A, 119A opening edge
126 photoresist layer
126A, 126B opening
L1 imaginary line
X1 first distance
X2 second distance
Y1 film thickness of insulating film
Y2 depth of recess

1.-4. (canceled)

5. An electrode structure for nitride semiconductor device comprising:
a nitride semiconductor multilayer structure having a heterointerface and further having a recess formed from a surface thereof toward the heterointerface;
an insulating film provided on a surface of the nitride semiconductor multilayer structure so as to be separated by a predetermined distance from an opening edge of the recess along the surface of the nitride semiconductor multilayer structure; and
an ohmic electrode provided from the recess of the nitride semiconductor multilayer structure to a surface of the insulating film so as to be in contact with the surface of the nitride semiconductor multilayer structure between the insulating film and the opening edge of the recess.

6. The electrode structure for nitride semiconductor device as claimed in claim 5, wherein
a first distance between an imaginary line extended from the opening edge of the recess in a normal direction of the surface of the nitride semiconductor multilayer structure and an outer edge of the ohmic electrode on the surface of the insulating film is
equal to or larger than a double of a second distance by which the insulating film is separated from the opening edge of the recess.

7. The electrode structure for nitride semiconductor device as claimed in claim 5, wherein
the nitride semiconductor multilayer structure includes:
a first GaN-based semiconductor layer; and
a second GaN-based semiconductor layer stacked on the first GaN-based semiconductor layer to from the heterointerface with the first GaN-based semiconductor layer.

8. A nitride semiconductor field effect transistor comprising:
the electrode structure for nitride semiconductor device as defined in claim 5;
a source electrode formed from the ohmic electrode;
a drain electrode formed from the ohmic electrode; and
a gate electrode provided on the nitride semiconductor multilayer structure.
